(19) United States
(12) Patent Application Publication
(10) Pub. No.: US 2014/0091461 A1
(43) Pub. Date: Apr. 3, 2014

(54) DIE CAP FOR USE WITH FLIP CHIP PACKAGE

(71) Applicant: Yuci Shen, Cupertino, CA (US)

(72) Inventor: Yuci Shen, Cupertino, CA (US)

(21) Appl. No.: 13/631,991

(22) Filed: Sep. 30, 2012

(51) Int. Cl. H01L 23/498; H01L 21/50

(52) U.S. Cl. 257/738; 257/737; 438/108; 257/E23.068; 257/E23.069; 257/E21.499

(57) ABSTRACT

A die cap for use with flip chip packages, flip chip packages using a die cap, and a method for manufacturing flip chip packages with a die cap are provided in the invention. A die cap encases the die of flip chip packages about its top and sides for constraining the thermal deformation of the die during temperature change. The CTE (coefficient of thermal expansion) mismatch between the die and substrate of flip chip packages is the root cause for warpage and reliability issues. The current inventive concept is to reduce the CTE mismatch by using a die cap to constrain the thermal deformation of the die. When a die cap with high CTE and high modulus is used, the die with the die cap has a relatively high overall CTE, reducing the CTE mismatch. As a result, the warpage and reliability of flip chip packages are improved.

### TECHNICAL FIELD OF THE INVENTION

The present invention generally relates to integrated circuit semiconductor packages. The present invention particularly relates to a die cap and its application for reducing the warpage and improving the reliability of flip chip semiconductor packages.

### BACKGROUND OF THE INVENTION

Flip Chip interconnect technology is extensively used for packaging semiconductor devices because of its capability for accommodating very high pin count per area. The very common semiconductor packages using flip chip interconnect technology includes flip chip packages. A flip chip package primarily comprises a die and a substrate, wherein the die with electrically conductive bumps such as solder bumps or cu pillar solder bumps on its active surface is attached on one side of the substrate. An underfill material is usually dispensed into the gap between the die and the substrate through a capillary force to protect solder bumps. Flip chip packages include flip chip ball grid array (FCBGA) packages, flip chip land grid array (FCLGA) packages and flip chip pin grid array (FCPGA) packages, depending on the type of electric contacts on the bottom side of the substrate of the flip chip packages. A large warpage is a big issue for flip chip packages using an organic substrate, especially for flip chip packages with a big substrate size and big die size. To control the warpage of flip chip packages, a ring type of stiffener or a hat type of lid is attached on the substrate. When using the conventional stiffener or lid to reduce the warpage of flip chip packages, the stress level inside flip chip packages is usually increased as a trade-off, leading to some stress-caused failure issues.

For a flip chip package using an organic substrate, the CTE of the substrate is about 15 ppm, while the CTE of die is about 3 ppm. The big CTE mismatch between the die and substrate is the root cause for such issues of the flip chip package as large warpage, dielectric layer cracking, bump bridging and bump cracking in its manufacture, application or reliability test.

There are efforts ongoing to reduce the warpage as well as to improve the reliability of flip chip packages. For example, some type of clips are described to reduce the warpage by clamping the substrate or holding the die onto the substrate when dispensing and curing an underfill material in prior arts. Also, a variety of stiffeners or lids are provided to reduce the warpage of the substrate of flip chip packages in prior arts.

FIGS. 1A and 1B illustrate a conventional type of lids for controlling the warpage of flip chip packages in prior arts. The lid illustrated in FIG. 1A is also referred to as a hat type of lid, consisting of a top piece 10, a side wall 12 and a foot edge 14. The hat type of lid can be inexpensively manufactured by stamping a metal sheet. The lid illustrated in FIG. 1B consists of a top piece 20 and a wide side wall 22. FIGS. 2A, 2B and 2C illustrate conventional flip chip packages using the conventional type of lids.

The lids in flip chip packages of FIGS. 2A and 2B have the same size as the substrate and are attached on the edge of the substrate. The lid in flip chip package of FIG. 2C is smaller than the substrate and is attached on an inner part of the substrate. The conventional flip chip packages comprise a die 32, a substrate 36 and a lid. The die 32 is electrically and mechanically connected on the substrate 36 through bumps 38 and an underfill material 40. The lid is attached on the substrate 36 and the die 32 through an adhesive material 34 and a thermal interface material 30. The major purpose of the lid is to constrain the thermal deformation of the substrate 36, reducing its warpage. It is noted that in these conventional flip chip packages, the lids don't constrain the die from its sides and there is a cavity between die sides and lid walls.

FIG. 3 illustrates a flip chip package using a die clip in prior art, in which a die 52 is electrically and mechanically connected on a substrate 58 through bumps 54 and an underfill material 56 and a die clip 50 is attached on the substrate after die attachment and prior to the dispensation of underfill material.

FIG. 4 illustrates a flip chip package using a multi-piece heat spreader 70 and 76 in prior art, in which a die 72 is electrically and mechanically connected on a substrate 80 through bumps 74 and an underfill material 78, and one piece 76 of the multi-piece heat spreader is attached on the substrate 80 after die attachment on substrate and prior to the dispensation of underfill material, and another piece 70 of the multi-piece heat spreader is attached on the substrate 80 after the dispensation of underfill material 78.

The major purpose for flip chip packages to use a lid is to reduce the warpage of the substrate. However, the conventional lids showed in FIGS. 1A and 1B and used in the flip chip packages illustrated in FIGS. 2A, 2B and 2C of prior arts mainly constrain the deformation or warpage of the substrate 36. A disadvantage of such an application of lids in flip chip packages is that there is a cavity between the die sides and the lid. As a result, the sides of the die 32 are not constrained effectively by the lids, giving a low efficiency for reducing the warpage of flip chip packages.

The basic concept of the prior arts illustrated in FIG. 3 and FIG. 4 is to prevent the movement of the die during and after the dispensation and curing of the underfill material by attaching a die clip or a piece of heat spreader on the substrate and adjacent to the die after the die attachment on substrate and prior to the dispensation of underfill material. For the prior art illustrated in the FIG. 3, the piece of heat spreader is called a die clip 50, which comprises a top portion and a side portion and has at least one opening on its side portion for the underfill material to get access. For the prior art illustrated in the FIG. 4, a multi-piece heat spreader is used, wherein one piece of the heat spreader 76 is attached on the substrate with at least one opening for the underfill material to get access. After dispensation and/or curing of the underfill material, the second piece of heat spreader 70 is used to close the opening of the first piece of heat spreader. A disadvantage of the prior arts illustrated in FIG. 3 and FIG. 4 is that the die clip or one piece of the multi-piece heat spreader is attached with the substrate prior to the dispensation of the underfill material into the gap between the die and the substrate. As a result, one or more openings on the side portion of the die clip or the multi-piece heat spreader is needed, leading to a complicated assembly process of a flip chip package using the die clip or multi-piece heat spreader.

The present invention provides a die cap with some inventive elements and its application to flip chip semiconductor packages. For a flip chip package using a die cap of the present invention, the die cap does not attach on the substrate prior to the dispensation of underfill material, but covers the die and bonds with the die through an adhesive material in order to control the thermal deformation of the die of the flip chip package. It is noted that the die cap of the present invention does not need any opening at its sides and the die cap bonds with the die not only at the top surface of the die but also at all the sides of the die. The material for making the die cap may be selected from high CTE and high modulus materials such as copper or copper alloys. Therefore, the die with the die cap (referred to as a capped die herein) has a relatively high overall CTE, reducing the CTE mismatch between the die and the substrate of flip chip package. As a result, the warpage of the flip chip packages using the die cap is reduced or eliminated as well as the reliability of flip chip packages on package level is improved in an efficient and costly effective way. Furthermore, when mounting a flip chip package with the die cap on a board or PCB for its field application, the board level reliability of the flip chip package is improved as well because the CTE mismatch is also the root cause for the reliability issue of the solder balls between the substrate and the board or PCB.

### SUMMARY OF THE INVENTION

The present invention describes a die cap with some specific elements, a flip chip package using a die cap, and a method for manufacturing a flip chip package with a die cap.

In one embodiment of the present invention, a die cap comprises a top piece, four side walls with or without a foot edge on the bottom of each side wall and some specific elements including 1) an edge notch on the inner surface and along the edge of the top piece of the die cap (referred to as an edge notch herein), 2) some bumps on the middle part of the inner surface of the top piece (referred to as middle bumps herein), 3) a top edge extending outwards from the top piece (referred to as a top edge herein), 4) side support walls or side support posts extending downwards from the top edge of the top piece (referred to as side support walls or side support posts herein). The terminologies of edge notch, middle bumps, top edge, side support walls and side support posts involved in the die cap of the present invention and the foot edge in the convention lid will be explained further with reference to their drawings below. Besides the major purpose of the die cap to control the warpage of the flip chip packages, these specific elements of the die cap of the present invention can improve the thermal performance and reduce the risk for the die cap to delaminate from the die.

In another embodiment, a flip chip package comprises a die, a substrate and a die cap, wherein the die and the die cap forms a capped die and an underfill material is dispensed into the gap between the capped die and the substrate through a capillary force to protect solder bumps. The die cap encases the die about its top and sides and bonds with the die through an adhesive material or the same underfill material.

In another preferred embodiment, a method for manufacturing a flip chip package using a die cap is provided, wherein the major assembly process steps include: attaching a die on a substrate, dispensing an underfill material into the gap between the die and the substrate, dispensing an adhesive material or the same underfill material on the die top surface or inside the die cap, covering the die cap onto the die using a pressure, and concurrently curing the package assembly.

The conventional method for reducing the warpage of flip chip packages is to constrain the thermal deformation of the substrate of flip chip packages by attaching a lid or a die clip on the substrate in prior arts. The inventive concept of present invention for reducing the warpage of flip chip packages is to directly constrain the thermal deformation of the die by bonding a die cap around the die of flip chip packages. The spirit of the present invention can be easily extended for reducing the warpage and improving the reliability of other semiconductor packages. For example, a die cap can cover an assembly of multiple stack dice to form a capped assembly of multiple stack dice. Accordingly, the warpage of flip chip packages using a capped assembly of multiple stack dice is reduced. More features and advantages of the present invention are described with reference to the detailed description of the embodiments of the present invention below.

### BRIEF DESCRIPTION OF THE DRAWINGS

FIGS. 1A and 1B is a cross-sectional view of conventional lids used in flip chip packages in prior arts, wherein the lid showed in FIG. 1A has a foot edge 14.

FIGS. 2A, 2B and 2C is a schematic cross-sectional view of flip chip packages using the conventional lids in prior arts.

FIG. 3 is a schematic cross-sectional view of a flip chip package using a die clip in prior art.

FIG. 4 is a schematic cross-sectional view of a flip chip package using a multi-piece heat spreader in prior art.

FIG. 5A-5D is a schematic cross-sectional view of a die cap with the elements of edge notch 140 or middle bumps 180 of one embodiment of the present invention, and FIG. 5E-5F is a schematic side view of the side walls 120 of the die cap which may be a whole piece or has a comb-like structure.

FIG. 6A-6C is a schematic cross-sectional view of a die cap with the feature of top edge 200 extending outwards from the top piece 100 of the die cap, and FIGS. 6D and 6E is a schematic top view of a die cap to illustrate the top view of the top edge 200 which may be a connected piece or four separate pieces of one embodiment of the present invention.

FIG. 7A-7E is a schematic cross-sectional view of a die cap with the elements of side support walls 300 or side support posts 300 extending downwards from the top edge 200 of the die cap of one embodiment of the present invention, and FIG. 7F-7G is a schematic side view of the side support walls 300 and side support posts 300.

FIG. 8A-8C is a schematic cross-sectional view of flip chip packages using a die cap of one embodiment of the present invention.

FIG. 9A-9C is a schematic cross-sectional view of flip chip packages using a die cap with more specific elements of one embodiment of the present invention.

FIG. 10 is a schematic cross-sectional view a molded flip chip package using a die cap of one embodiment of the present invention.

FIG. 11 is a schematic cross-sectional view of a flip chip package using a capped assembly of multiple stack dice of one embodiment of the present invention.

FIG. 12 is a schematic cross-sectional view of an assembly process of a method for manufacturing a flip chip package using a die cap of one embodiment of the present invention.

FIG. 13A is a schematic cross-sectional view of another assembly process of a method for manufacturing a flip chip package using a die cap of one embodiment of the present invention, and FIG. 13B is a schematic cross-sectional view of the corresponding flip chip package which has a large underfill fillet 900 surrounding the die cap 1000.

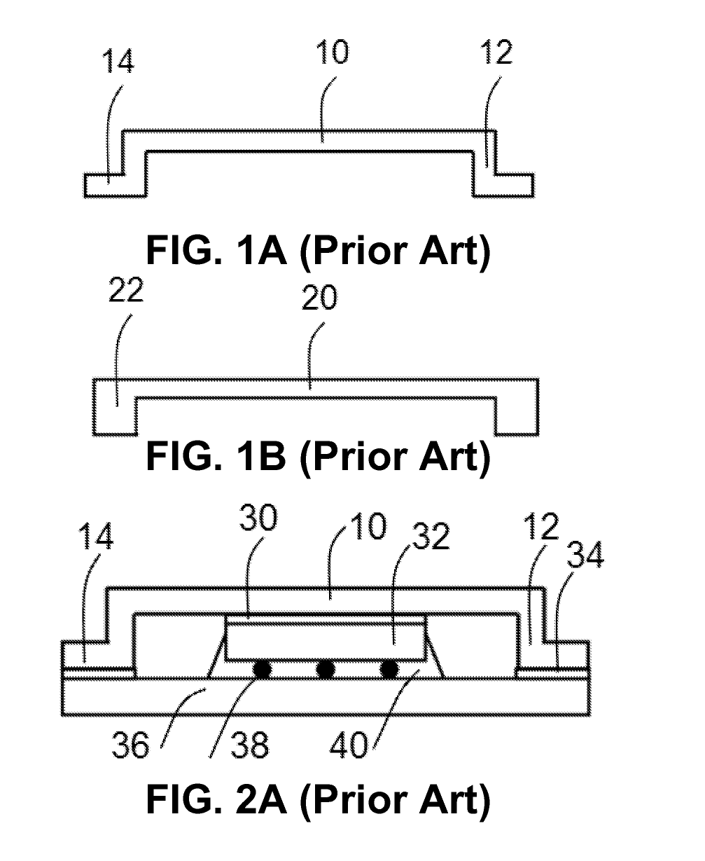

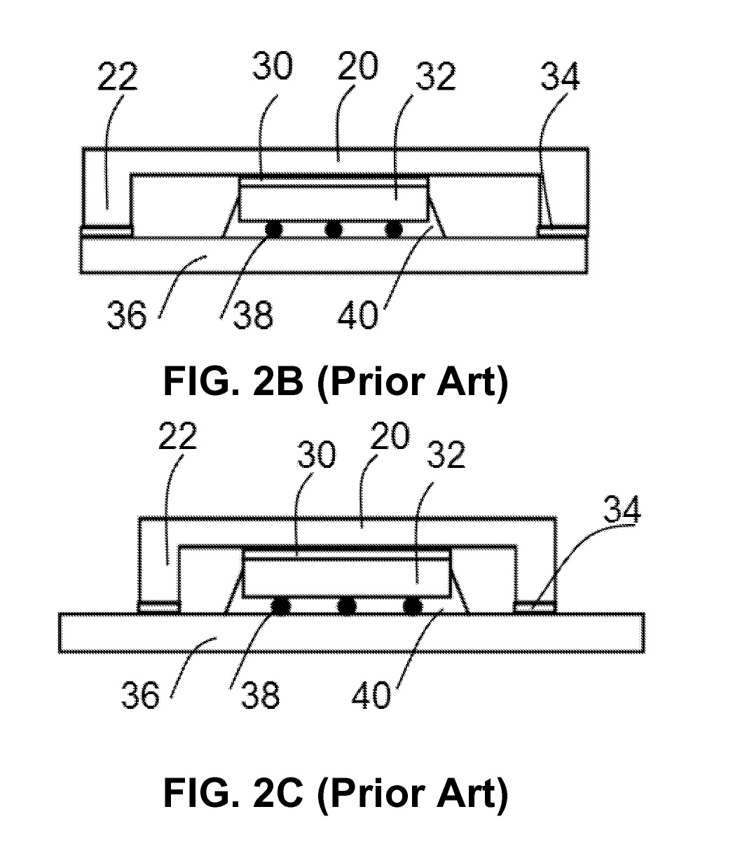

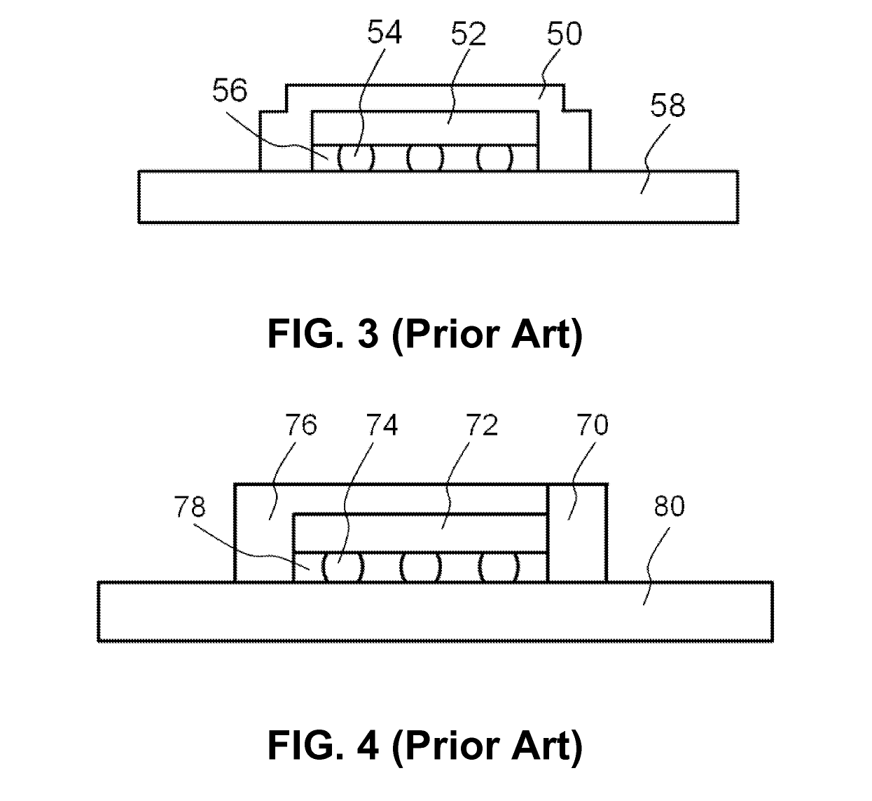

### DETAILED DESCRIPTION OF THE PREFERRED EMBODIMENT

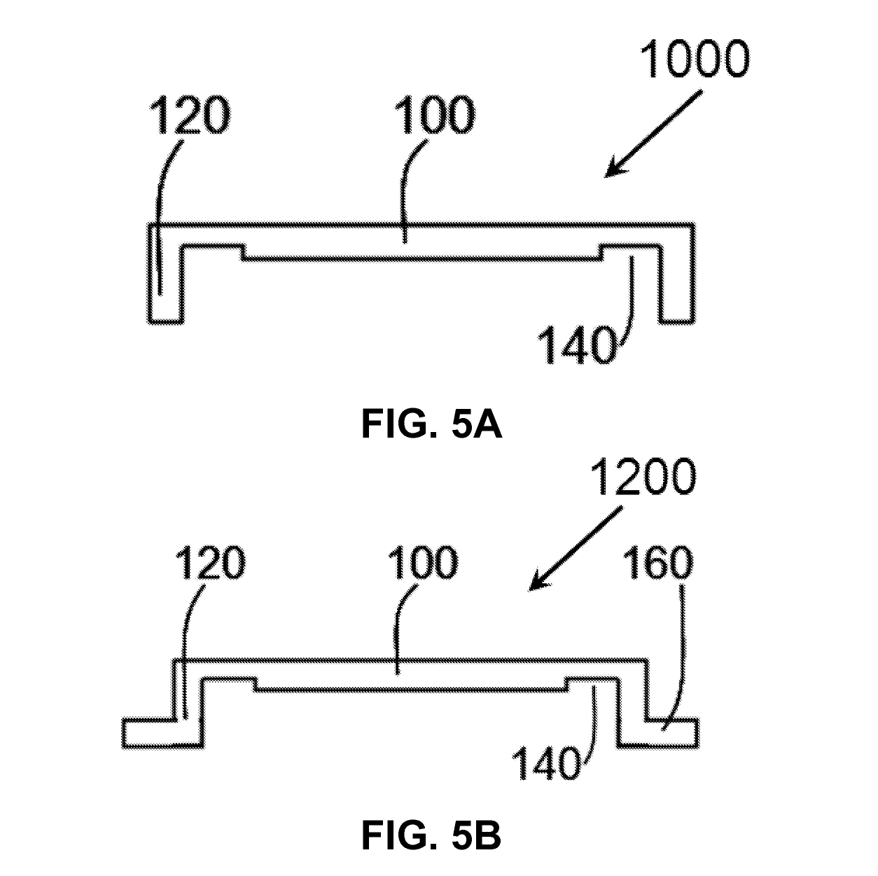

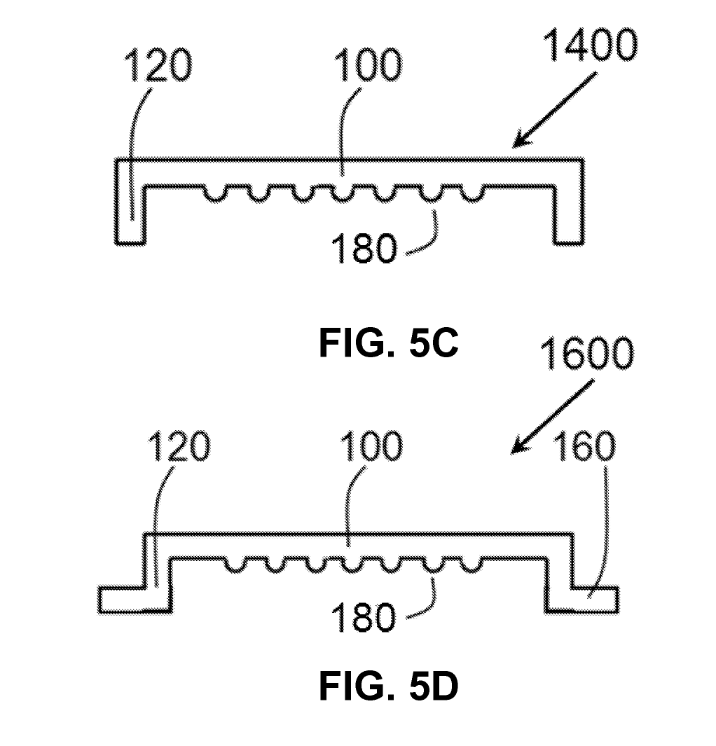

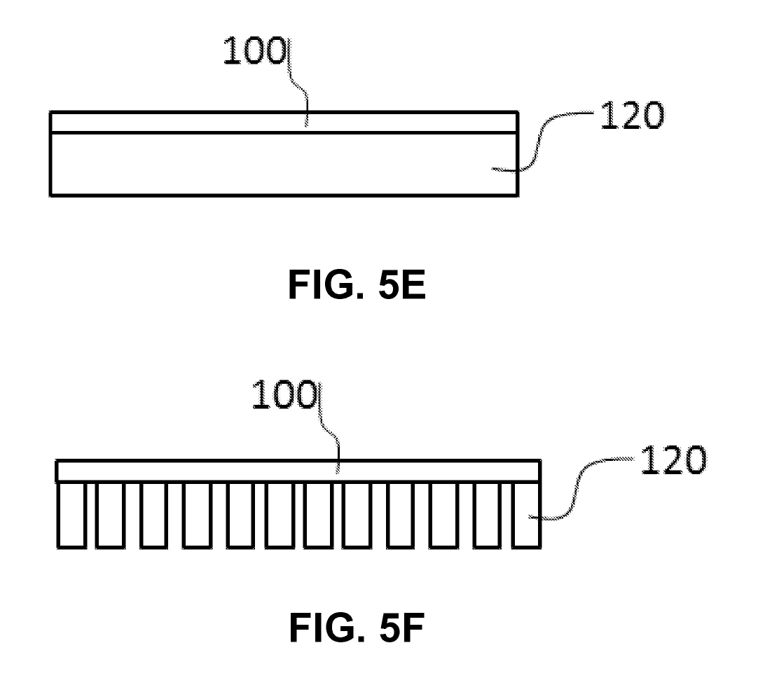

Referring to FIG. 5A, a schematic cross-sectional diagram of a die cap 1000 is shown, wherein the die cap comprises a top piece 100, side walls 120 and an edge notch 140 on the inner surface and along the edge of the top piece 100. The purpose of the edge notch 140 is to make the thickness of adhesive layer between a die and the die cap thick and thin on the outer and inner parts separately when covering the die cap on the die. As a result, the risk of delamination failure between the die and die cap may be reduced without significantly affecting thermal dissipation capability from die to die cap. Referring to FIG. 5B, a schematic cross-sectional diagram of a die cap 1200 is showed, wherein the die cap comprises a top piece 100, four side walls 120, an edge notch 140 along the edge of top piece and a foot edge 160 at the bottom of each side wall. The die caps 1000 and 1200 showed in FIGS. 5A and 5B have an edge notch 140, which is the first specific feature of the die cap of one embodiment of the present invention. Referring to FIGS. 5C and 5D, the die caps 1400 and 1600 have some middle bumps 180 inside and on the middle part of the top piece 100 of the die cap, which is the second specific feature of the die cap of one embodiment of the present invention. The purpose of the middle bumps 180 is similar to that of the edge notch 140, is to reduce the risk of delamination failure between the die and die cap without significantly affecting thermal dissipation capability from die to die cap. Referring to FIGS. 5E and 5F, each side wall 120 of the die cap may be a whole piece or may have a comb-like structure. When bonding a die cap with a die, the die cap with a whole piece of side walls is better for constraining the thermal deformation of the die, while the die cap with a comb-like structure of side walls is better for reducing the risk of the delamination between the die cap and the die.

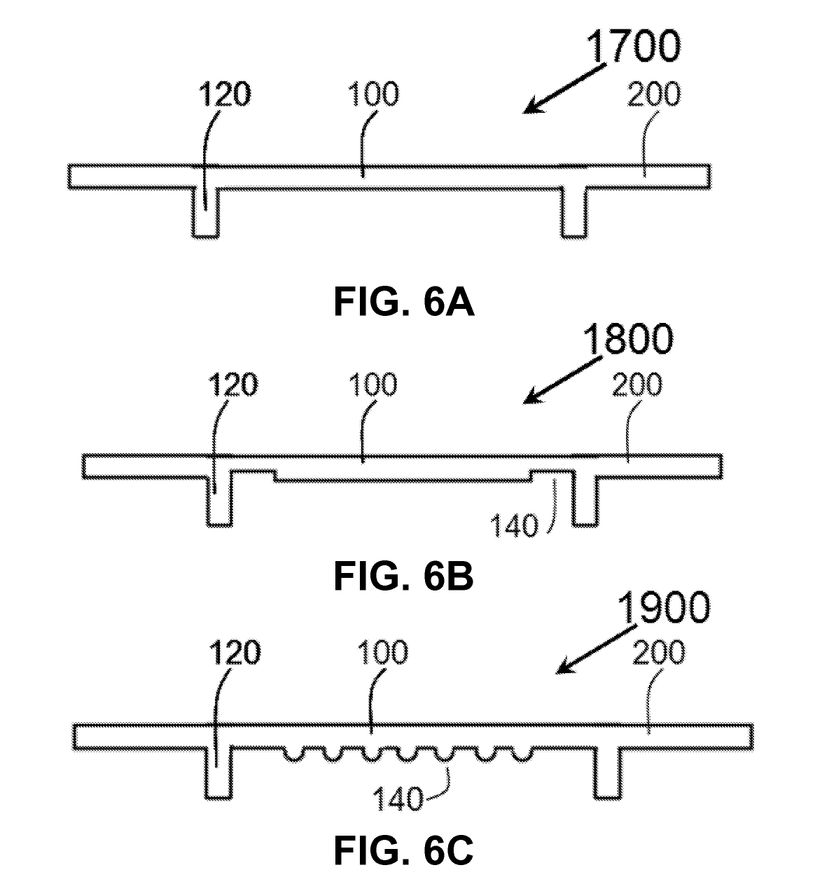

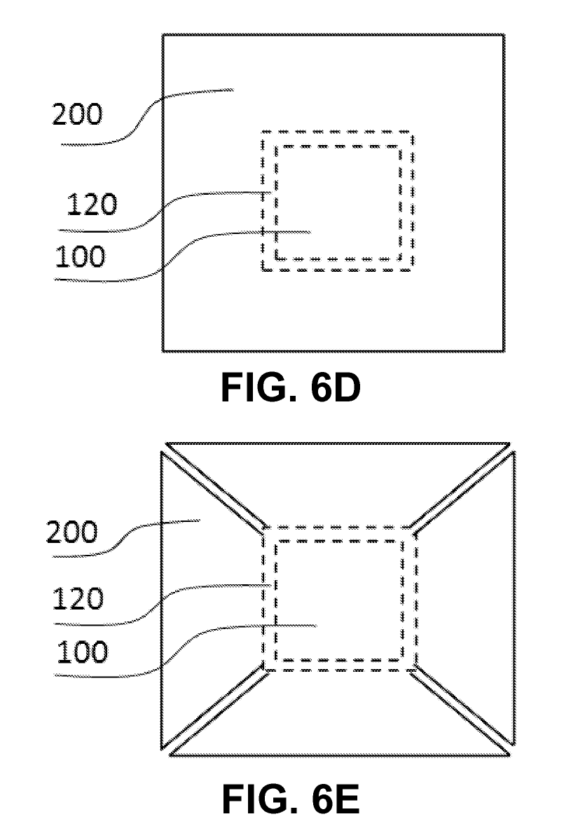

Referring to FIG. 6A to 6C, the die caps 1700, 1800 and 1900 have a top edge 200 extending outwards from the top piece 100 of the die caps, which is the third specific feature of the die cap of one embodiment of the present invention. The design of a top edge 200 is for a better heat dissipation when covering the die cap on a die. The top edge 200 may have any shape and may be a whoe piece or some separate pieces from its top view. FIGS. 6D and 6E are two examples of the top edge 200 from its top view. The die cap with some separate pieces of top edge 200 as showed in FIG. 6E may be inexpensively manufactured by folding a piece of material, such as a metal sheet.

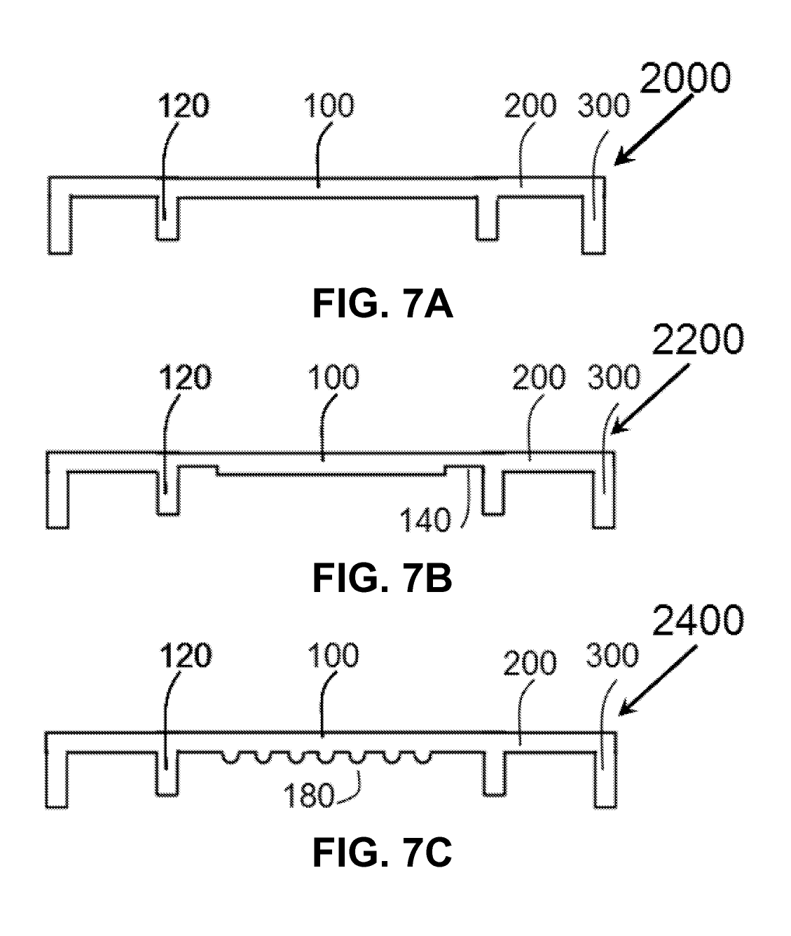

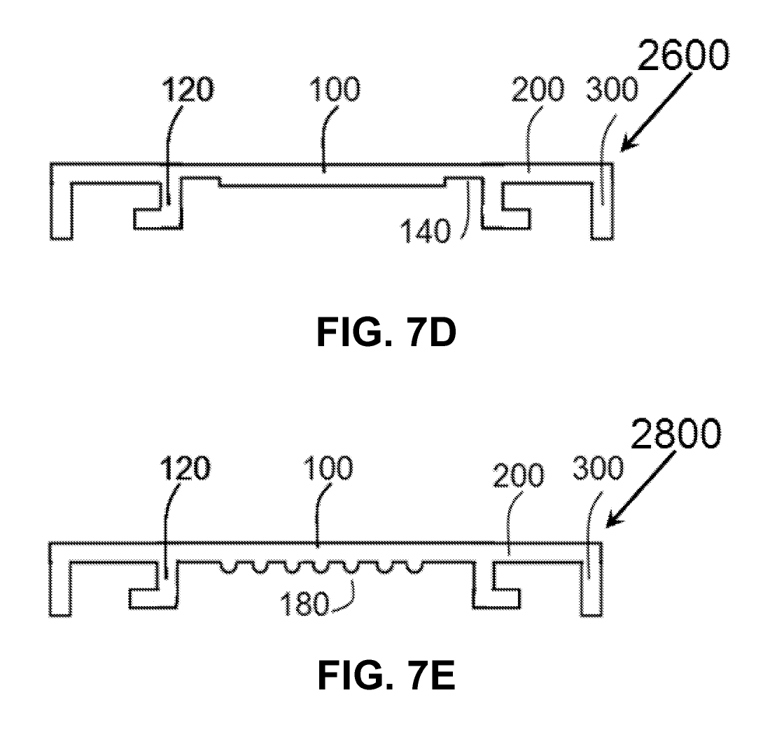

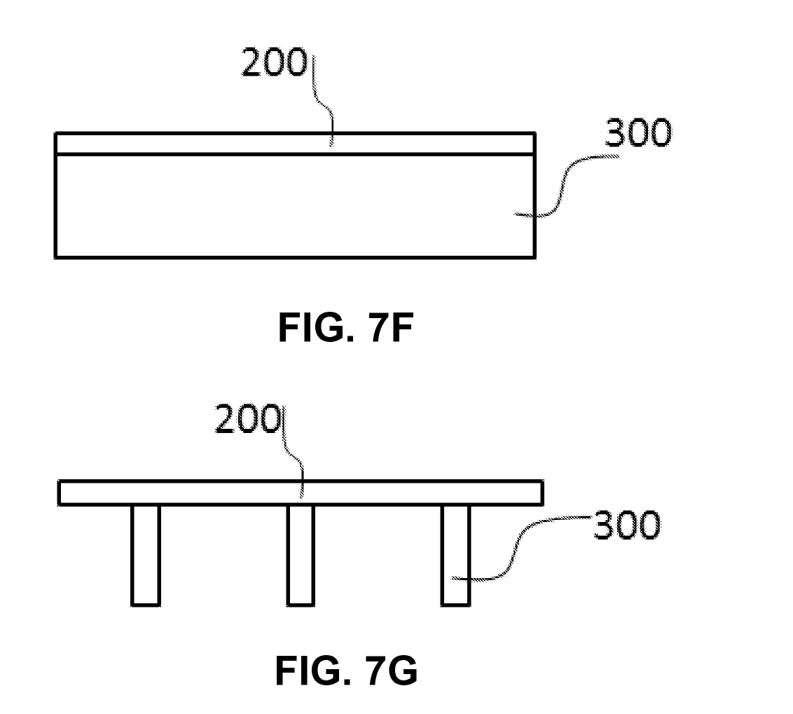

Referring to FIG. 7A to 7E, the die caps 2000, 2200, 2400, 2600 and 2800 have the side support walls or support posts 300 extending downwards from the top edge 200 of the top piece 100 of the die caps, which is the fourth specific feature of the die cap of one embodiment of the present invention. When the die cap is made from a thin piece of metal, the top edge 200 may be too flexible. So, the purpose of the side support walls or support posts 300 is to support the top edge 200. The side support walls or support posts 300 only stand on the substrate without attaching with the substrate of flip chip packages. FIG. 7F-7G is the side view of the side support walls or support posts 300 wherein the number of the support posts 300 (which is three herein) may be various.

For flip chip packages using a die cap, the die cap bonds with the die through an adhesive material to constrain the thermal deformation of the die during a temperature change. The material for making the die cap may be a metal and have high CTE (coefficient of thermal expansion), high modulus and high thermal conductivity. Preferably, the material of the die cap is copper, copper alloy, aluminum, aluminum alloy, iron, or stainless steel. The thickness of the die cap is about 0.1 mm to 1.0 mm. And the thickness of the die cap is preferably about 0.15 mm to 0.5 mm. The thickness of the adhesive material filling the gap between the die cap and the die sides may be about 0.001 mm to 2 mm. The thickness of the adhesive material filling the gap between the die cap and the die sides is preferably about 0.05 mm to 0.5 mm. The gap between the die cap and the die top is preferably about 0.001 mm to 0.25 mm. More preferably, the gap between the die cap and the die top is about 0.01 mm to 0.1 mm. For the die cap with a comb-like structure of side walls, the thickness of the adhesive material filling the gap between the side walls of the die cap and the die sides may be small.

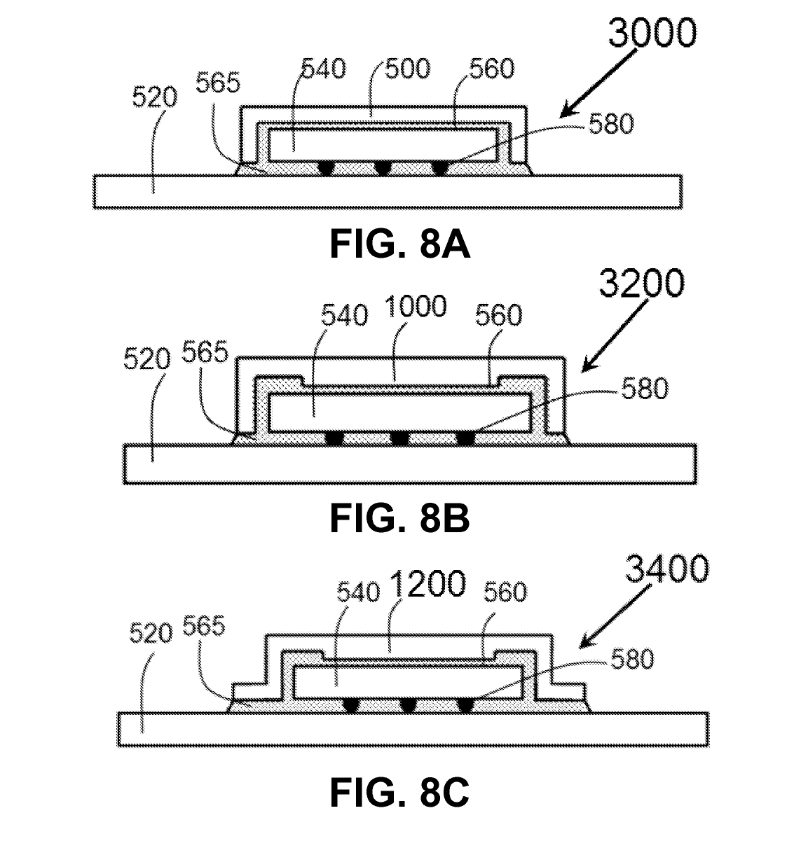

Referring to FIGS. 8A, 8B and 8C, flip chip packages 3000, 3200 and 3400 using a die cap are illustrated, which comprise a die 540, a die cap 500, 1000 or 1200, a substrate 520, bumps 580, adhesive material 560 and underfill material 565, wherein the die cap bonds with the die through an adhesive material 560 which may be the same material as the underfill material 565 as illustrated in FIGS. 8A, 8B and 8C. One advantage of using the same underfill material as the adhesive material 560 to bond the die cap with the die is that the adhesive material 560 and the underfill material 565 has a good combination underneath the bottom of the side walls of the die cap. And another advantage of using the same underfill material as the adhesive material 560 to bond the die cap with the die is that the assembly process for manufacturing flip chip packages with a die cap becomes much simpler.

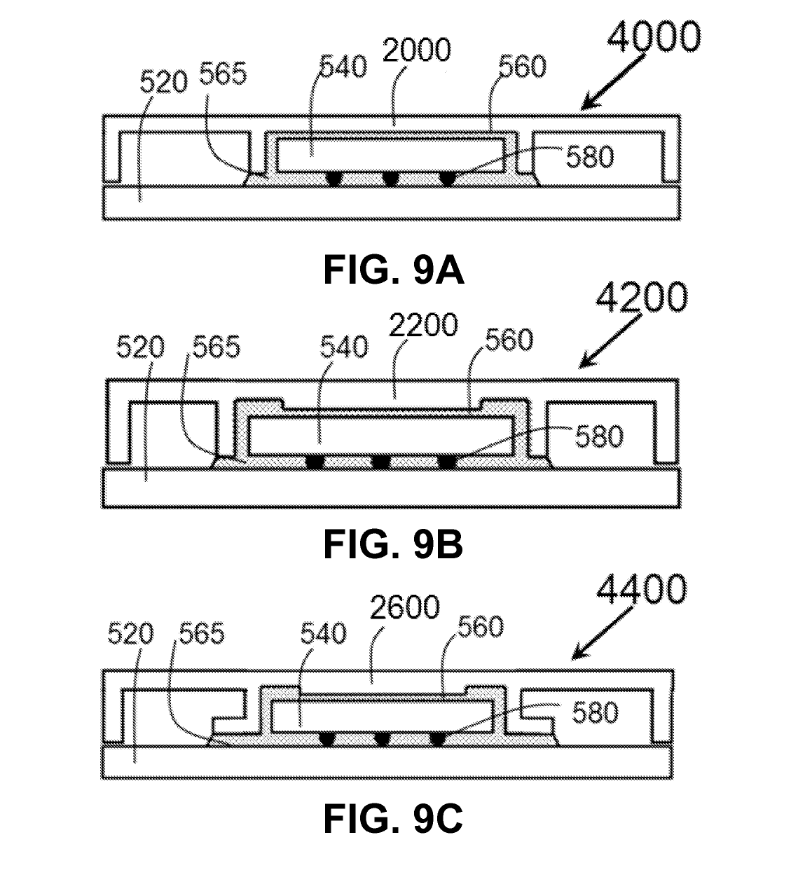

The die cap integrated in a flip chip package for encasing the die of the flip chip package may have one or more specific elements of the die caps illustrated in FIG. 5, FIG. 6 and FIG. 7. FIG. 9A-9C describe flip chip packages 4000, 4200 and 4400 using a die cap which has the specific elements of the edge notch 140, the top edge 200, and side support walls or support posts 300. The die cap integrated in flip chip packages may have the specific feature of middle bumps 180 inside and on the middle part of the top piece of the die cap. The flip chip packages with the specific feature of middle bumps 180 are not illustrated through schematic diagram herein.

The die cap as showed in FIG. 5B and the flip chip package using the die cap as showed in FIG. 8C are preferred from a trade-off consideration among manufacture, cost, reliability and warpage control, wherein the length of the foot edge 160 is about 0.1 mm to 2 mm, and preferably about 0.2 mm to 1.0 mm, depending on the size of the flip chip package.

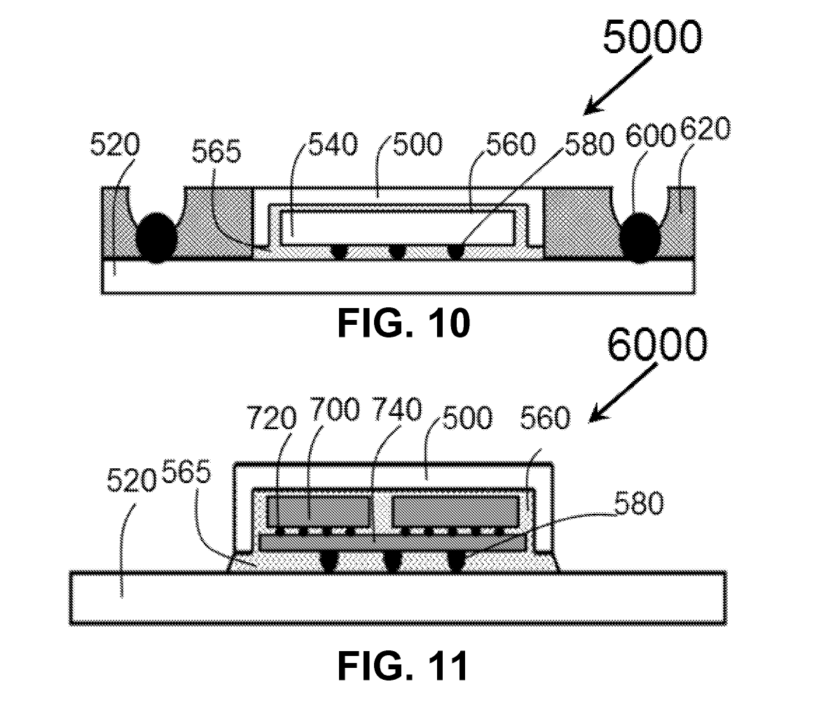

The inventive concept of the present invention is to use a die cap to constrain the thermal deformation of the die of a flip chip package. The inventive concept of the present invention may be easily combined with some conventional concepts to form new package structures. For example, FIG. 10 illustrates a molded flip chip package 5000 using a die cap 500, wherein the die cap 500 is molded in a mold compound 620. The type of molded flip chip package 5000 is used for package on package (PoP) assembly, wherein the top solder balls 600 are for connection with a top package. For package on package (PoP) assembly, the warpage control of the bottom package is critical for a reliable connection of the top and bottom packages. Integrating a die cap 500 with the molded flip chip package 5000 can reduce the warpage significantly.

The inventive concept of the present invention may also be easily extended to the case of multiple dice or multiple stack dice. FIG. 11 illustrates a flip chip package 6000 with an assembly of multiple stack dice using a die cap, wherein the assembly of multiple stack dice comprises a silicon interposer die 740 and two top dice 700 which are electronically and mechanically bonded together through micro bumps 720 and underfill material 560, and a die cap 500 which bonds with the assembly of multiple stack dice through an adhesive material 560.

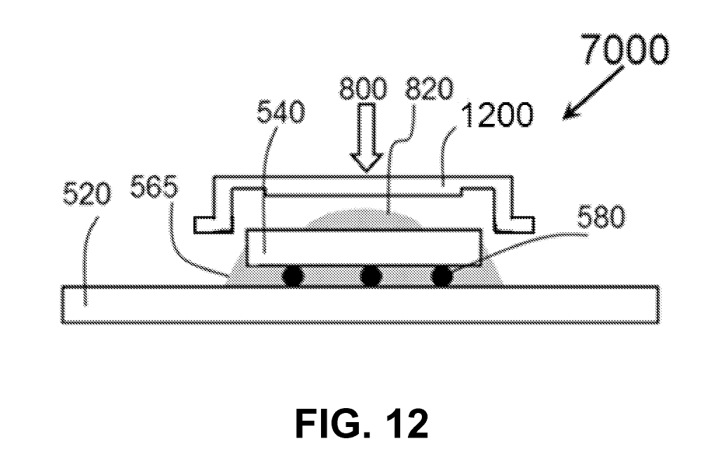

FIG. 12 illustrates an assembly process 7000 of a method for manufacturing a flip chip package using a die cap, wherein after the die attachment on substrate, the underfill material 565 is dispensed into the gap between the die 540 and the substrate 520 first, then an adhesive or underfill material 820 is dispensed on the die top or inside the die cap, and then the die cap is placed onto the die 120 through a pressure 800. The assembly method may produce various dimensions of underfill filet by using the same underfill material as the adhesive material and by controlling the amount of the underfill material 820. The pressure 800 should be right for the adhesive or underfill material 820 to spread and flow down from the die top for filling the gaps between the die cap and the die and to get combined with the underfill material 565. It is noted that for the purpose of heat dissipation, the underfill material 820 used for bonding the die cap and the die may have high thermal conductive fillers.

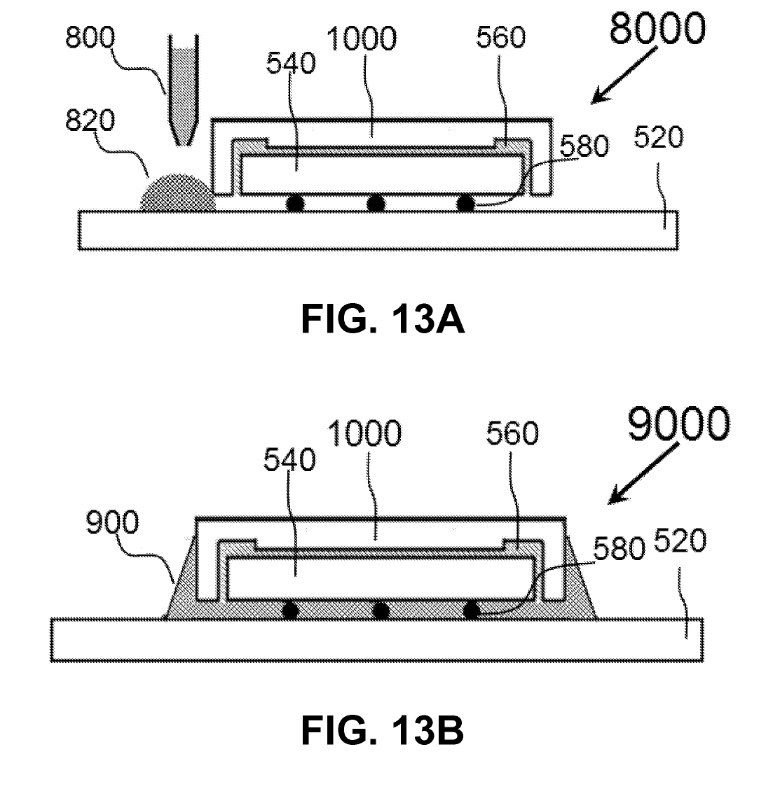

FIG. 13A illustrates another assembly process 8000 of the method for manufacturing a flip chip package using a die cap, wherein after the die attachment on substrate, covering the die cap 1000 on the die first, then viewing the die with the die cap as a capped die and dispensing an underfill material 820 into the gap between the capped die and the substrate. Because the underfill material 820 is dispensed from the outside of the die cap 1000 by a dispenser 800, the flip chip package manufactured by the assembly process 8000 may have a large underfill fillet surrounding the die cap 1000 as showed in FIG. 13B, a flip chip package 9000 having a large underfill fillet 900.

For the conventional method to manufacture a flip chip package using a lid, the underfill material is cured prior to the lid attachment. The curing process of the underfill material develops a large warpage in the flip chip package. Then, attaching a lid on the substrate is only to adjust the large warpage, causing a high level of stress in the flip chip package. One major feature of the present method for manufacturing a flip chip package using a die cap showed in FIG. 12 and FIG. 13 is that the underfill material is cured after covering the die cap on the die. As a result, the thermal deformation of the die is constrained during the curing of the underfill material, reducing or eliminating the warpage development of the flip chip package during the curing process of the underfill material.

The flip chip packages using a die cap of the present invention have the following advantages as compared to the conventional flip chip packages using a lid or a heat spreader in prior arts: 1) lower warpage and stress, 2) lower risk of delamination failure for underfill material, 3) lower risk of die cracking during its testing or operation, 4) lower risk of bump cracking, and 5) larger substrate top surface for mounting other components.

Although the present invention is described in some details for illustrative purpose with reference to the embodiments and drawings, it is apparent that many other modifications and variations may be made without departing from the spirit and scope of the present invention.

What is claimed is:

1. A die cap for use with flip chip packages, comprising a top piece, four side walls with or without a foot edge at the bottom of each side wall, and any one or more of the four specific elements: 1) an edge notch on the inner surface and along the edge of the top piece, 2) some middle bumps on the middle part of the inner surface of the top piece, 3) a top edge extending outwards from the top piece, and 4) side support walls or side support posts extending downwards from the top edge of the die cap.

2. The die cap of claim 1, each side wall consists of a whole piece or some separate pieces with a comb-like structure.

3. The die cap of claim 1, wherein the top edge consists of a connected piece or some separate pieces.

4. The die cap of claim 1, wherein the material for making the die cap is a metal sheet with thickness from 0.1 mm to 1 mm, has high coefficient of thermal expansion, high thermal conductivity and high Young's modulus, and is selected from copper, nickel-plated copper, copper alloy, aluminum, anodized aluminum, aluminum alloy, iron, and stainless steel.

5. A flip chip package, comprising a die, a substrate and a die cap wherein the die and the substrate are electrically and mechanically connected through electrically conductive bumps and an underfill material, the die cap includes at least a top piece and four side walls with or without a foot edge at the bottom of each side wall, the die cap encases the die about its top and four sides, and the die cap bonds with the die at its top and four sides through an adhesive material for constraining the thermal deformation of the die of the flip chip package during temperature change.

6. The flip chip package of claim 5, wherein the adhesive material (which is for bonding the die cap with the die) and the underfill material (which is for filling the gap between the die and substrate) get combined underneath the bottom of the side walls of the die cap.

7. The flip chip package of claim 5, wherein the adhesive material for bonding the die cap with the die is the same underfill material as used for filling the gap between the die and substrate such that the two materials have a better combination underneath the bottom of the side walls of the die cap.

8. The flip chip package of claim 5, wherein each side wall of the die cap consists of a whole piece or pieces with a comb-like structure.

9. The flip chip package of claim 5, wherein the die cap has any one or more of the four specific elements: 1) an edge notch on the inner surface and along the edge of the top piece of the die cap, 2) some middle bumps on the middle part of the inner surface of the top piece of the die cap, 3) a top edge extending outwards from the top piece, and 4) side support walls or side support posts extending downwards from the top edge of the die cap.

10. The flip chip package of claim 5, wherein the material for making the die cap is a metal sheet with thickness from 0.1 mm to 1 mm, has high coefficient of thermal expansion, high thermal conductivity and high Young's modulus, and is selected from copper, nickel-plated copper, copper alloy, aluminum, anodized aluminum, aluminum alloy, iron, and stainless steel.

11. The flip chip package of claim 5, wherein the die is an assembly of multiple dice or multiple stack dice.

12. The flip chip package of claim 5, wherein a mold compound encapsulates over the substrate and around the die cap, forming a molded flip chip package using a die cap.

13. The flip chip package of claim 5, wherein the substrate has balls, pins or electric contact lands on its bottom side to form a flip chip ball grid array (FCBGA) package, a flip chip pin grid array (FCPGA) package or a flip chip land grid array (FCLGA) package using a die cap.

14. A method for manufacturing a flip chip package using a die cap, comprising the assembly process steps: 1) attaching a die on a substrate, 2) dispensing an underfill material into the gap between the die and the substrate, 3) dispensing an adhesive material on the top of the die or inside the cavity of the die cap, 4) positioning and covering a die cap on the die, 5) concurrently curing the adhesive material and the underfill material, and 6) mounting an array of solder balls on the bottom side of the substrate for flip chip ball grid array packages.

15. The method for manufacturing a flip chip package using a die cap of claim 14, wherein the adhesive material dispensed on the top of the die or inside the cavity of the die cap in the process step 3) is the same underfill material as used for filling the gap between the die and substrate in the process step 2).

16. The method for manufacturing a flip chip package using a die cap of claim 14, wherein a pressure is used in the process step 4) for squeezing the adhesive material on the top of the die or inside the cavity of the die cap to flow down for filling the gap between the die sides and the side walls of the die cap and the gap between the bottom of the side walls of the die cap and the substrate wherein the adhesive material gets combined with the underfill material dispensed in the assembly process step 2).

17. The method for manufacturing a flip chip package using a die cap of claim 14, wherein the assembly process step 2) is done after the assembly process steps 3) and 4), that is, covering a die cap on the die first, then viewing the die with the die cap as a capped die and dispensing an underfill material from one side of the die cap into the gap between the capped die and the substrate, and then the assembly process steps 5) and 6) are followed.

18. The method for manufacturing a flip chip package using a die cap of claim 17, wherein the adhesive material dispensed on the top of the die or inside the cavity of the die cap is the same underfill material as used for filling the gap between the die and substrate.

19. The method for manufacturing a flip chip package using a die cap of claim 17, wherein the adhesive material for bonding the die cap with the die partially fills the gap between the die sides and the side walls of the die cap, and the remaining gap not filled by the adhesive material is filled by the underfill material in the mean time when the underfill material fills the gap between the capped die and the substrate in the assembly process step of dispensing an underfill material from one side of the die cap into the gap between the capped die and the substrate.
